(19) United States
(12) Patent Application Publication
(10) Pub. No.: US 2006/0097370 A1
(43) Pub. Date: May 11, 2006

(54) Stepped integrated circuit packaging and mounting

(75) Inventors: Gerald Keith Bartley, Rochester, MN (US); Richard Boyd Ericson, Rochester, MN (US); Wesley David Martin, Elgin, MN (US); Benjamin William Mashak, Rochester, MN (US); Trevor Joseph Timpane, Rochester, MN (US); Ay Vang, Vadnais Heights, MN (US)

Correspondence Address: IBM CORPORATION, 3605 HIGHWAY 52 NORTH, DEPT 917, ROCHESTER, MN, 55901-7829, US

(73) Assignee: International Business Machines Corporation, Armonk, NY (US)

(21) Appl. No.: 10/970,410

(22) Filed: Oct. 21, 2004

(51) Int. Cl. H01L 23/02

(52) U.S. Cl. 257/678

(57) ABSTRACT

An electronic assembly and system and method implementing the same are disclosed herein. The electronic assembly includes an IC carrier package having circuitry contained within a housing unit. The IC carrier package includes a connector interface for electrically coupling the IC carrier package circuitry to a printed circuit board. The connector interface is further characterized as having a graduated step surface contour with one or more electrical contacts disposed on at least two graduated step connector surfaces of the connector interface. The electronic assembly further includes a multilayer printed circuit board having a mounting site cavity for mounting the IC carrier package. The mounting site cavity includes having at least two seating surfaces offset in a graduated step manner for receivably seating the at least two graduated step connector surfaces of the IC carrier package connector interface.

### BACKGROUND OF THE INVENTION

1. Technical Field

The present invention relates generally to electronic circuit packaging and mounting. In particular, the present invention relates to an improved apparatus and method for mounting an integrated circuit chip onto a printed circuit board.

2. Description of the Related Art

Printed circuit boards (PCBs), also commonly referred to as printed wiring boards (PWBs), are utilized to electrically interconnect integrated circuits (ICs), and other electrical components such as capacitors and resistors. Population densities of PCBs have increased dramatically over the years in response to ever increasing IC complexity and the continual demand for miniaturized IC device applications. A typical computer motherboard, for example, includes hundreds of IC chips and other surface mount components.

Conductive trace lines, pads and through lines are among the electrical interconnect features typical of PCB interconnect designs. On the component side, an IC chip, for example, typically includes a body having external pins or other electrical contacts that are electrically and mechanically coupled to corresponding pads on the PCB. To accommodate increasing circuit design complexity and density in combination with reduced PCB footprint, multiple layer PCBs have been developed wherein several layers of conductors are separated by layers of dielectric material. The outer surface layers of the PCB include metallized patterns that provide the interconnects and mounting pads for components that are ultimately coupled, such as by soldering, to the PCB. The multiple layer circuit boards are typically designed such that the intermediate conductor layers may provide power, ground, and/or signaling planes for the PCB.

To accommodate such PCB multi-layering, mounting designs further incorporate vias and through-vias or through-holes to enable electrical interconnection from a surface disposed pad to one of the intermediate metallization layers. Specifically, the conductive PCB layers are interconnected using vias which provide interconnection between adjacent PCB conductive layers and through-vias or through-holes which provide interconnection between non-adjacent layers. Vias are typically plated with conductive material and are located across the PCB and connected to mounting locations on the outer conductive planes using conductive traces. In this manner, a multi-layer PCB provides a three-dimensional interconnect for the surface mounted components.

While necessitating the foregoing developments in compact IC mounting design, continued increases in circuit density and speed have begun posing problems for conventional multi-layered PCBs. The conventional multi-layer PCB design includes a fabrication process in which sequential conductive planes are separated by layers of dielectric material with circuit interconnect patterns formed on each plane. The planes are interconnected between the dielectric layers by drilling, laser etching or otherwise boring the via holes which are then suitably plated. Given its micro-scale and sensitive contamination requirements, the via-forming technology has run into cost and size limitations. Furthermore, the mounting pads for integrated circuits and surface mount components on the outer surface of a PCB are not directly connected to the via through holes, but are instead usually connected to the plated through-hole locations using patterned conductive traces. Additional circuit board layout space is therefore required to route the component mounting pads to the respective vias that connect the traces to their respective signal or power/ground planes, often with undesirable effects such as via coupling, cross-talk, and other logistical problems.

With the increased population density of IC devices on multi-layer PCBs, electrical interference and PCB surface footprint layout limitations caused by the aforementioned pad routing and via placement pose substantial packaging design limitations. Therefore, a need exists for an improved IC device packaging and mounting apparatus that addresses these and other problems unresolved by the prior art.

### SUMMARY OF THE INVENTION

An IC carrier package apparatus, a printed circuit board apparatus and an electronic assembly incorporating the same are disclosed herein. The electronic assembly includes an IC carrier package having circuitry contained within a housing unit. The IC carrier package includes a connector interface for electrically coupling the IC carrier package circuitry to a printed circuit board. The connector interface is further characterized as having a graduated step surface contour with one or more electrical contacts positioned on at least two graduated step connector surfaces of the connector interface. The electronic assembly further includes a multilayer printed circuit board having a mounting site cavity for mounting the IC carrier package. The mounting site cavity includes having at least two seating surfaces offset in a graduated step manner for seating the at least two graduated step connector surfaces of the IC carrier package connector interface.

The above as well as additional objects, features, and advantages of the present invention will become apparent in the following detailed written description.

### BRIEF DESCRIPTION OF THE DRAWINGS

The novel features believed characteristic of the invention are set forth in the appended claims. The invention itself however, as well as a preferred mode of use, further objects and advantages thereof, will best be understood by reference to the following detailed description of an illustrative embodiment when read in conjunction with the accompanying drawings, wherein:

FIG. 1 illustrates a cross-section side profile view of an electronic assembly in accordance with the present invention;

FIG. 2 depicts an overhead view of a multilayer printed circuit board having an stepped integrated circuit mounting site in accordance with the present invention;

FIG. 3 illustrates an underneath view of an IC carrier package having a stepped connector interface in accordance with the present invention;

FIG. 4 depicts a cross-section side profile view of an electronic assembly in accordance with an alternate embodiment of the present invention; and

FIG. 5 illustrates a cross-section side profile view of an electronic assembly in accordance with an alternate embodiment of the present invention.

### DETAILED DESCRIPTION OF ILLUSTRATIVE EMBODIMENT(S)

The present invention addresses interconnect challenges relating to packaged integrated circuits (ICs) mounted to printed circuit boards (PCBs). To this end, the present invention is generally directed to an IC carrier package and associated PCB designs. As utilized herein, an “electronic assembly” or “circuit board assembly” may comprise one or more carrier packages attached to one or more printed circuit boards. These assemblies come in a variety of sizes and configurations such as compact cellular phone assemblies or larger backplane assemblies that form the cores of mainframe computer systems.

The IC carrier packages used in circuit board assemblies come in many forms including socket-type and surface mount. A common surface mount packaging structure is known as Ball Grid Array (BGA) packaging. Conventional BGA packaging enables ICs to fit into smaller board footprints by utilizing an array of substantially co-planar solder ball connections on one or more surfaces of the module housing. While IC carrier packages depicted in the exemplary embodiments herein employ some aspects of BGA packages, it should be noted that other types of chip carriers including those having pins instead of solder ball connectivity may be used without departing from the spirit or scope of the present invention.

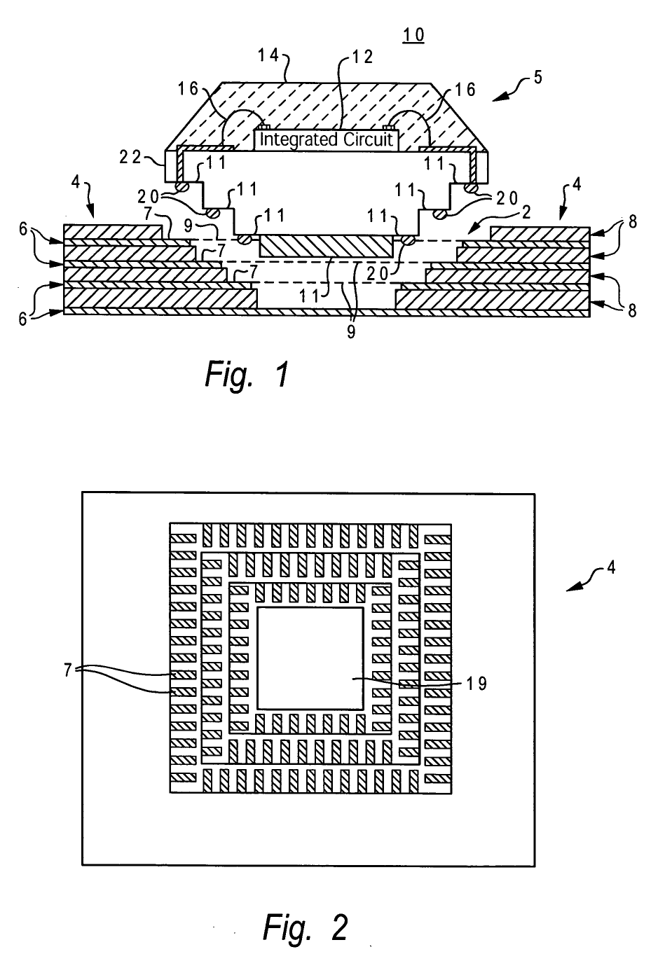

With reference now to the figures wherein like reference numerals refer to like and corresponding parts throughout, and in particular with reference to FIG. 1, there is illustrated a cross-section side profile view of an electronic assembly in accordance with the present invention. Specifically, an electronic assembly 10 is depicted as generally comprising an IC carrier package 5 and a multilayer PCB 4. IC carrier package 5 includes a housing unit 14, which may be, for example, a plastic molded box in which an IC chip 12 is protectively encapsulated. IC carrier package 5 further includes a package substrate 22 joined with housing unit 14 on which the IC chip 12 is mounted.

In conventional BGA packaging design, the package substrate portion of the IC carrier package provides a substantially planar bottom surface on which an array of solder ball electrical contacts are disposed in an array pattern. In contrast, and as further illustrated in FIG. 1, the bottom mounting side of package substrate 22 has a graduated step surface contour that ramps generally upwardly and outwardly from the center of the bottom of package substrate 22. One or more electrical contacts in the form of one or more solder balls 20 are disposed on each of the stepped surfaces of package substrate 22.

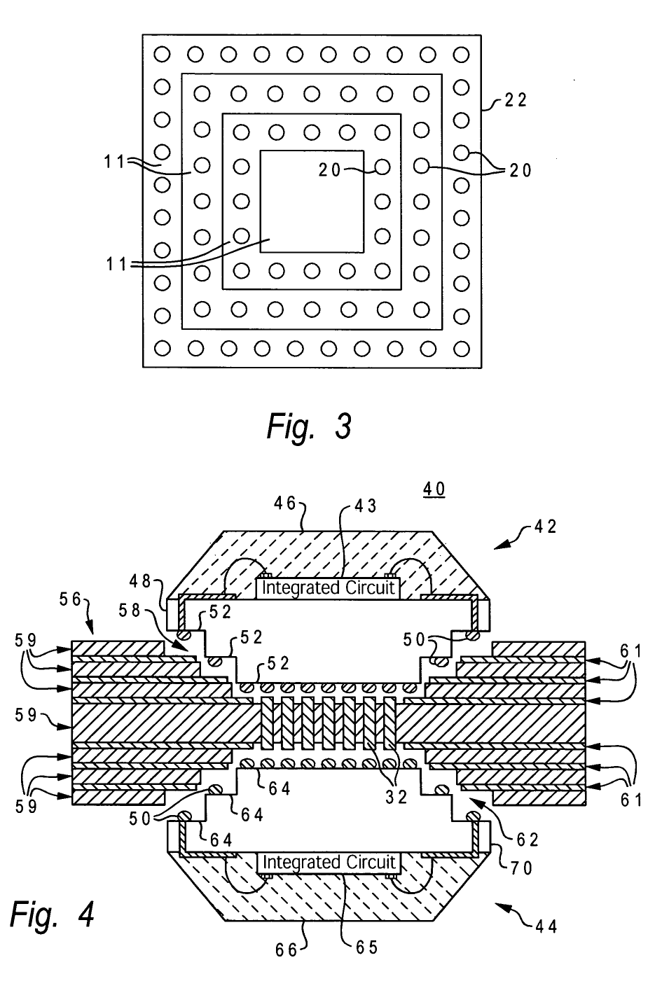

An alternate view of the connector interface contour formed by package substrate 22 is illustrated in FIG. 3. In particular, FIG. 3 illustrates an underneath view of the IC carrier package 5 displaying the concentric arrangement of the multiple graduated step connector surfaces 11. Disposed along each of the graduated step surfaces 11 is a row of solder balls 20 that provide the electrical connectivity between the circuitry within IC carrier package 5 and a board connection device such as a PCB. The lowermost level of graduated step connector surfaces 11 may include solder balls or may alternately comprise a uniform conductive layer. It should be noted that while the concentric arrangement is depicted as substantially square, alternate embodiments of the invention may employ circular or otherwise curvilinear or other substantially symmetric rectilinear arrangements.

Referring again to FIG. 1, the circuitry within IC chip 12 is electrically coupled through package substrate 22 using conductive traces or wires including gold wires 16 to solder balls 20. In accordance with the present invention, the connector interface formed by the concentrically disposed graduated step surfaces 11 of package substrate 22 is designed for mechanically mounting and electrically coupling the carrier package 5 to multilayer PCB 4. While the depicted embodiment uses wirebonding (wires 16) the present invention is not limited to the manner of chip-to-package connectivity such that the invention is equally applicable to any other materials and attachments techniques such as flip-chip design.

As IC carrier package 5 is the interface for the semiconductor IC chip 12, PCB 4 serves as the interface for the IC carrier package. PCB 4 may be constructed from organic laminated materials consisting of a resin (epoxy, polymide, phenolic, etc.) embedded with a reinforcement material such as glass, paper, etc., and have copper foil forming inner and outer metallization layers.

As depicted in FIG. 1 and the overhead view of FIG. 2, multilayer PCB 4 generally comprises a mounting site cavity 2 defined therein. Mounting site cavity 2 is characterized as having multiple seating surfaces offset in a graduated step manner for receivably seating the multiple graduated step connector surfaces 11 of the IC carrier package connector interface. The concentrically graduated mounting surface contour of mounting site cavity 2 can be seen from the overhead view of FIG. 2 in conjunction with the partial cross-section view of FIG. 1.

Multi-layer PCB 4 includes multiple metallization layers 6 separated in an interleaved manner by multiple insulative layers 8. As shown by the depicted side-profile cross-section view, the offset seating surfaces are disposed coplanar with seating planes 9 within the mounting site cavity 2 substantially coinciding with the conductive metallization layers 6. As further depicted in FIGS. 1 and 2, each of the offset seating surfaces includes one or more conductive pads 7 disposed thereon such that the conductive pads 7 align with the connector interface electrical contacts (e.g. solder balls 20) when IC carrier package 5 is mounted within mounting site cavity 2. The lowermost seating surface 19 within mounting site cavity 2 may comprise a solid conductor surface and may be used to supply power or ground references to the IC chip 12 via the lowermost, or base, graduated step connector surface 11.

FIG. 4 depicts a cross-section side profile view of an electronic assembly in accordance with an alternate embodiment of the present invention. In particular, an electronic assembly 40 is shown in a back-to-back configuration in which a first IC carrier package 42 and a second IC carrier package 44 are mounted in substantially aligned opposition on the opposing board surfaces of a PCB 56. Each of carrier packages 42 and 44 are designed in substantial conformity with the IC carrier package design depicted in FIG. 1. Similar to IC carrier package 5, IC carrier package 42 includes an IC chip 43 protectively encapsulated within a molded housing unit 46. The housing unit 46 and IC chip 43 are supported by a package substrate 48 which may or may not be an extension of the chip housing unit. Package substrate 48 is contoured similarly to package substrate 22 to define multiple graduated step connector surfaces 52 that are preferably concentrically arranged and on which solder balls 50 are disposed. Electronic assembly 40 further includes a second IC carrier package 44 similarly comprising an IC chip 65 contained within a housing unit 66, and a package substrate 70 having concentrically arranged graduated stepped surfaces 64 on which solder balls 50 are disposed.

In accordance with the depicted embodiment, IC carrier package 44 is mounted onto multilayer PCB 56 in a substantially aligned manner across from carrier package 42. To provide the substantially aligned configuration shown in FIG. 4, PCB 56 includes a pair of mounting site cavities 58 and 62 that are oppositely disposed on opposing board surfaces. Cavities 58 and 62 are individually structured in substantial conformity to the PCB mounting site design described with reference to FIGS. 1 and 2. That is, each of mounting site cavities 58 and 62 are characterized as having multiple seating surfaces offset in a graduated step manner for receivably seating the multiple graduated step connector surfaces of the respective IC carrier package connector interfaces formed by package substrates 48 and 70.

As with PCB 4, multilayer PCB 56 includes multiple metallization layers 61 separated in an interleaved manner by multiple insulative layers 59 with the offset seating surfaces disposed in seating planes within the mounting site cavities 58 and 62 substantially coinciding with the conductive metallization layers 61. Furthermore, each of the offset seating surfaces includes one or more conductive pads disposed thereon and aligning with the connector interface electrical contacts (e.g. solder balls 50) when the carrier packages 42 and 44 are mounted within their respective mounting site cavities. In contrast to the embodiment shown in FIGS. 1-3, wherein the lowermost seating surface 19 within mounting site cavity 2 comprised a solid conductor surface used to supply power or ground references, PCB 56 further includes vias 32 formed between the lowermost seating surfaces of mounting site cavities 58 and 62. In this manner, chip-to-chip signaling paths from carrier package 42 to carrier package 44 are minimized resulting in lower susceptibility to cross-talk and other forms of signal line interference.

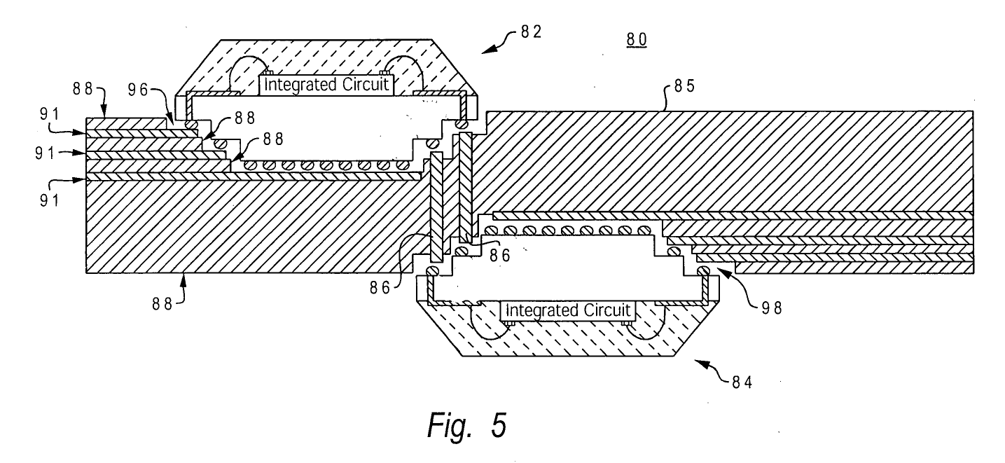

An alternate embodiment of the present invention is depicted in FIG. 5. Specifically, there is illustrated a cross-section side profile view of an electronic assembly 80 utilizing an offset module design that incorporates the structural and functional features of the embodiment shown in FIGS. 1-3 with those of the back-to-back embodiment illustrated in FIG. 4. Similar to assembly 40, electronic assembly 80 generally comprises a pair of IC carrier packages 82 and 84 designed substantially identically to the carrier design described with reference to FIGS. 1, 3 and 4 and mounted onto a multilayer PCB 85. Furthermore, IC carrier packages 82 and 84 are mounted within partially offset mounting site cavities 96 and 98, respectively, within a multilayer PCB 85.

As with PCBs 4 and 56, multilayer PCB 85 includes multiple metallization layers 91 separated in an interleaved manner by multiple insulative layers 88 with the offset seating surfaces disposed in seating planes within the mounting site cavities 96 and 98 substantially coinciding with the conductive metallization layers 91. Furthermore, each of the offset seating surfaces includes one or more conductive pads disposed thereon and aligning with the connector interface solder balls when the carrier packages 82 and 84 are mounted within their respective mounting site cavities 96 and 98. Similar to the embodiment shown in FIGS. 1-3, the lowermost seating surface within each of mounting site cavities 96 and 98 may comprise a solid conductor surface used to supply power or ground references or alternatively may include an array of solder balls attached thereto. PCB 85 further includes vias 86 formed between the overlapping portion of the seating surfaces between mounting site cavities 96 and 98. In this manner, a portion of the chip-to-chip signaling paths from carrier package 82 to carrier package 84 are minimized while maximum power delivery is maintained on the lowermost seating surfaces of mounting site cavities 96 and 98.

While the invention has been particularly shown and described with reference to a preferred embodiment, it will be understood by those skilled in the art that various changes in form and detail may be made therein without departing from the spirit and scope of the invention.

1. An electronic assembly comprising an integrated circuit (IC) carrier package having circuitry contained within a housing unit, said IC carrier package including a connector interface for electrically coupling the IC carrier package circuitry to a printed circuit board, wherein said connector interface is further characterized as having a graduated step surface contour with one or more electrical contacts disposed on at least two graduated step connector surfaces of the connector interface.

2. The electronic assembly of claim 1, wherein said graduated step surface contour is concentrically graduated.

3. The electronic assembly of claim 1, wherein said IC carrier package encapsulates an IC chip containing said circuitry.

4. The electronic assembly of claim 3, wherein said IC carrier package comprises a package substrate through which the IC chip is electrically coupled to the connector interface electrical contacts.

5. The electronic assembly of claim 1, wherein the connector interface electrical contacts comprise solder balls.

6. The electronic assembly of claim 1, further comprising a multilayer printed circuit board having a first mounting site cavity formed on a first surface of said multilayer printed circuit board for mounting said IC carrier package, said first mounting site cavity having at least two seating surfaces offset in a graduated step manner for seating the at least two graduated step connector surfaces of the IC carrier package connector interface.

7. The electronic assembly of claim 6, wherein said mounting site cavity is further characterized as having a concentrically graduated mounting surface contour.

8. The electronic assembly of claim 6, wherein said multilayer printed circuit board is characterized as including multiple conductive layers separated in an interleaved manner by substrate layers, said at least two offset seating surfaces disposed in seating planes within said mounting site cavity substantially coinciding with the conductive layers.

9. The electronic assembly of claim 8, wherein each of said at least two offset seating surfaces includes one or more conductive pads disposed thereon such that the conductive pads align with the connector interface electrical contacts when said IC carrier package is mounted within said mounting site cavity.

10. An electronic assembly comprising:
an integrated circuit (IC) carrier package containing an IC chip within a housing unit, said IC carrier package including a connector interface for electrically coupling the IC carrier package circuitry to a printed circuit board, wherein said connector interface is further characterized as having a graduated step surface contour with one or more electrical contacts disposed on at least two graduated step connector surfaces of the connector interface; and
a multilayer printed circuit board having a first mounting site cavity formed on a first surface of said multilayer printed circuit board for mounting said IC carrier package, said first mounting site cavity having at least two seating surfaces offset in a graduated step manner for seating the at least two graduated step connector surfaces of the IC carrier package connector interface.

11. The electronic assembly of claim 10, wherein said graduated step surface contour of said IC carrier package is concentrically graduated.

12. The electronic assembly of claim 10, wherein said IC carrier package comprises a package substrate through which the IC chip is electrically coupled to the connector interface electrical contacts.

13. The electronic assembly of claim 10, wherein the connector interface electrical contacts comprise solder balls.

14. The electronic assembly of claim 10, wherein said mounting site cavity is further characterized as having a concentrically graduated mounting surface contour.

15. The electronic assembly of claim 10, wherein said multilayer printed circuit board is characterized as including multiple conductive layers separated in an interleaved manner by substrate layers, said at least two offset seating surfaces disposed in seating planes within said mounting site cavity substantially coinciding with the conductive layers.

16. The electronic assembly of claim 15, wherein each of said at least two offset seating surfaces includes one or more conductive pads disposed thereon such that the conductive pads align with the connector interface electrical contacts when said IC carrier package is mounted within said mounting site cavity.

17. The electronic assembly of claim 6, said multilayer printed circuit board further including a second mounting site cavity formed on a second surface of said multilayer printed circuit board opposing said first surface, said second mounting site cavity having at least two seating surfaces offset in a graduated step manner for seating at least two graduated step connector surfaces of an IC carrier package connector interface, said second mounting site cavity disposed in overlapping opposing alignment with respect to said first mounting site cavity.

18. The electronic assembly of claim 17, further comprising conductive vias formed through said multilayer printed circuit board between seating surfaces of said first and second mounting site cavities.

19. The electronic assembly of claim 10, said multilayer printed circuit board further including a second mounting site cavity formed on a second surface of said multilayer printed circuit board opposing said first surface, said second mounting site cavity having at least two seating surfaces offset in a graduated step manner for seating at least two graduated step connector surfaces of an IC carrier package connector interface, said second mounting site cavity disposed in overlapping opposing alignment with respect to said first mounting site cavity.

20. An electronic assembly comprising:
an integrated circuit (IC) carrier package containing an IC chip within a housing unit, said IC carrier package including a connector interface for electrically coupling the IC carrier package circuitry to a printed circuit board, wherein said connector interface is further characterized as having a graduated step surface contour with one or more electrical contacts disposed on at least two graduated step connector surfaces of the connector interface; and
a multilayer printed circuit board having a first mounting site cavity formed on a first surface of said multilayer printed circuit board for mounting said IC carrier package, said first mounting site cavity having at least two seating surfaces offset in a graduated step manner for seating the at least two graduated step connector surfaces of the IC carrier package connector interface, said multilayer printed circuit board further including a second mounting site cavity formed on a second surface of said multilayer printed circuit board opposing said first surface, said second mounting site cavity having at least two seating surfaces offset in a graduated step manner for seating at least two graduated step connector surfaces of an IC carrier package connector interface, said second mounting site cavity disposed in overlapping opposing alignment with respect to said first mounting site cavity.
